(19) United States
(12) Patent Application Publication
(10) Pub. No.: US 2010/0317191 A1
(43) Pub. Date: Dec. 16, 2010

(54) COPPER INTERCONNECTION FOR FLAT PANEL DISPLAY MANUFACTURING

(76) Inventors: Akinobu Nasu, Ibaraki (JP); Yi-Tsung Chen, Taiwan (CN); Shyuan-Fang Chen, Taipei (TW)

Correspondence Address: American Air Liquide, Inc.;Intellectual Property Dept., 2700 Post Oak Boulevard, Suite 1800, Houston, TX, 77056, US

(21) Appl. No.: 12/066,929

(22) PCT Filed: Mar. 15, 2007
(86) PCT No.: PCT/EP07/52466

§ 371 Date: Sep. 1, 2010

(51) Int. Cl. H01L 21/768

(52) U.S. Cl. 438/674; 438/678; 257/E21.575

(57) ABSTRACT

A method of depositing a copper interconnection layer on a substrate for use in a flat panel display interconnection system, comprising the steps of: a) coating said substrate with a photoresist layer; b) patterning said photoresist layer to obtain a patterned photoresist substrate comprising at least one trench patterned into said photoresist layer; c) providing a first catalyzation layer onto the patterned photoresist substrate; d) providing an electroless plated layer of an insulation layer deposited onto said first catalyzation layer; e) removing the successively superimposed photoresist layer, catalyzation layer and insulation layer except in the at least one trench, to obtain a pattern of the first catalyzation layer with an insulation layer deposited thereon.

The invention relates to a method of depositing a copper interconnection layer on a substrate for use in a flat panel display interconnection system.

The basic principles of TFT-LCD panels are well known, and they are used widely as computer screens or TV displays. In the panels, each pixel has an address given by its line number and column number in the matrix of pixels constituting the screen. There is one pixel at each intersection of a line and a column which are interconnected through a thin film transistor which is activated (conductive state) when both corresponding line and column are activated, the pixel electrodes being thereby brought under appropriate voltage to generate the appropriate pixel color. When the corresponding line and column (the pixel address) are deactivated then the transistor switches off the connection to the related pixel, which comes back to its original color.

When the size of the display panel increases, the frequency of the driving signals needs to be increased, thereby generating an increase of the parasitic capacitance of these lines, which in turn means a delay in the propagation of the driving signals. In an attempt to reduce these delays, it has been already suggested, e.g. in the article entitled “Low Resistance Copper Address line for TFT-LCD”—Japan Display' 89—pp. 498-501, to use sputtered copper instead of aluminum, as the gate electrode material of the thin film transistor and related matrix interconnection lines or buses, because the resistivity of copper is much lower compared to that of aluminum.

Various etching processes are used to make transistors. However, dry etching of copper is not effective because most of copper species are not volatile and/or etching gas and by-products are corrosive in most cases.

In the semiconductor industry, the Damascene Process has been developed, wherein a via-hole is made first then copper is filled into the hole by combination of dry (sputtering) and wet processes (electroplating).

In the flat panel display industry, the use of copper is considered to reduce the signal delay as in the semiconductor industry, but the Damascene Process is not considered as appropriate since such process requires much more steps than the current wiring process and has not been experienced with large substrates (e.g. 1.5 m×1.8 m for G5 TFT-LCD panel). It is anticipated that the use of such process would raise some technical hurdles and increase the manufacturing cost. On the other hand, wet etching of copper is also studied.

However, it is more difficult to control the shape of the copper interconnections, because isotropic wet etching is used but not anisotropic wet etching.

One may believe that it should be easy to combine the Electroless Plating process and the Lift-off process. However, it has been difficult in practice to combine lithography with Electroless Plating. This is essentially due to the existence of many steps of pre-treatment to be carried out in the Electroless Plating process said pretreatment steps using alkaline solutions that most Photoresists cannot stand.

When the Electroless Cu Plating is performed on the photoresist pattern, said pattern dissolves into the plating solution and the desired pattern cannot be obtained anymore. Furthermore, these Photoresist layers cannot stand for a long time (>1 min) under an operation temperature higher than 90° C.

The process for depositing a copper interconnection layer on a substrate for use in a flat panel display interconnection system according to the invention comprises the steps of:

a) Coating said substrate with a photoresist layer;

b) Patterning said photoresist layer to obtain a patterned photoresist layer comprising at least one trench patterned into said photoresist layer;

c) Providing a first catalysation layer onto said patterned photoresist layer, said first catalysation layer having a better adhesion to the substrate in the at least one trench than to the photoresist layer.

By using such a process, it is thus possible to create a pattern on which a copper layer (plus at least an insulation layer underneath) will adhere to make the copper interconnection system.

The next two steps of the process essentially consist in depositing an insulation layer in the at least one trench and removing the photoresist pattern, these two steps being carried out in whatever order.

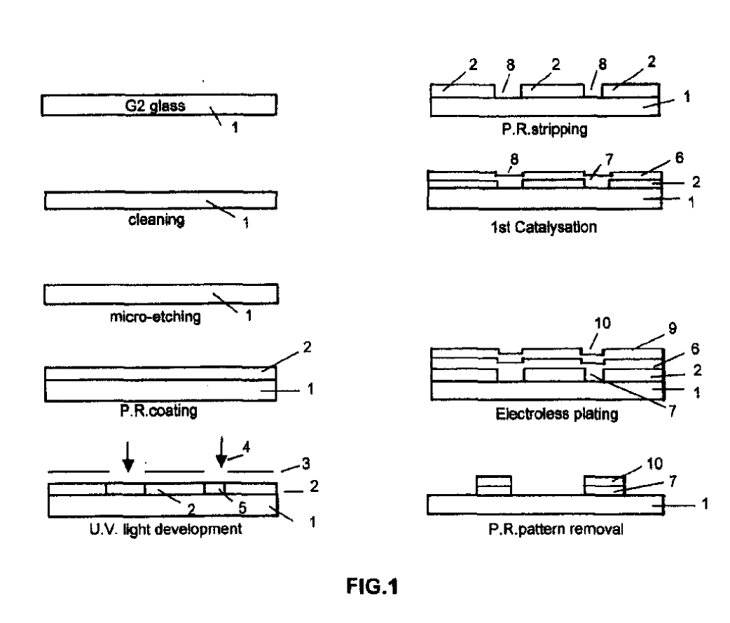

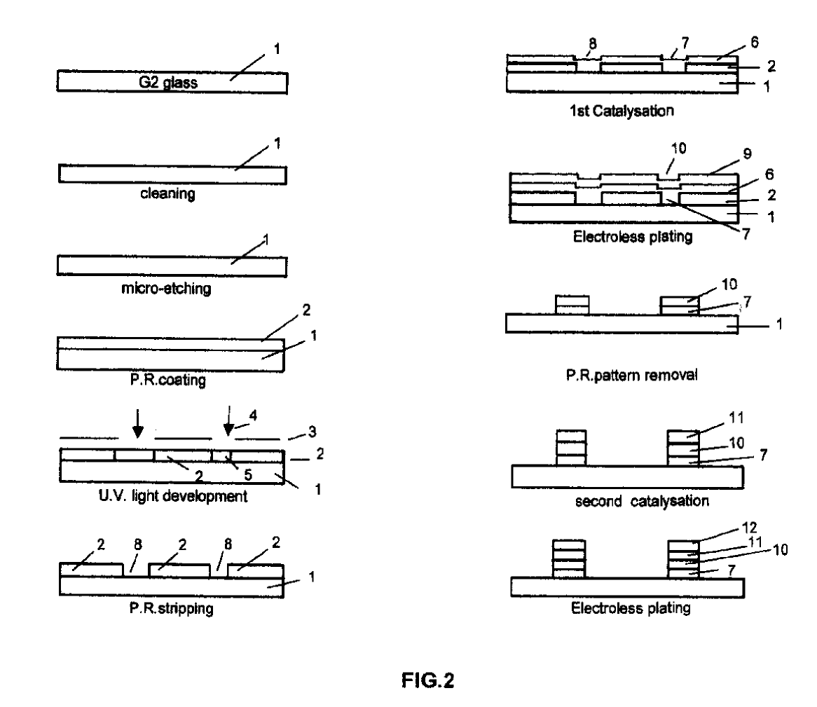

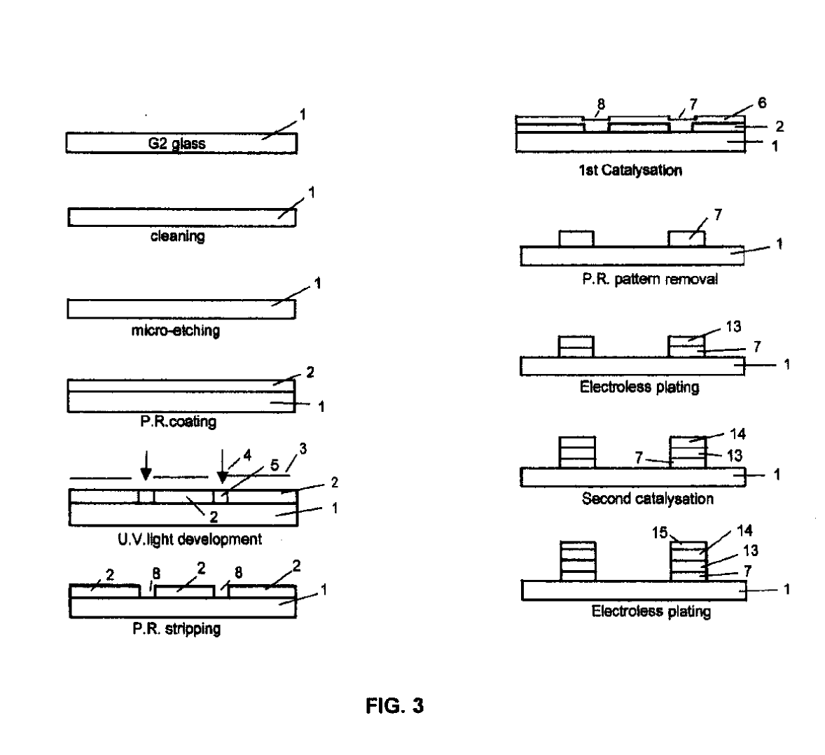

According to a first embodiment of the invention (FIGS. 1 and 2), the Electroless Plating step of the insulation layer is carried out after said first catalysation step, followed by the photoresist pattern removal step, while according to a second embodiment (FIG. 3) the photoresist pattern removal step is carried out after the first catalysation step, followed by the Electroless Plating step of the insulation layer.

Both embodiments provide a substrate with a pattern of the insulation layer superimposed on the pattern of the first catalysation layer on the substrate.

Whatever embodiment is used, the next steps usually comprise a second catalysation step and an Electroless Plating step for said copper deposition.

Therefore, according to a first embodiment, the process of the invention further comprises the steps of:

d) Providing an electroless plated layer of an insulation layer deposited onto said first catalysation layer; and

e) Removing the successively superimposed photoresist layer, first catalysation layer and insulation layer except at the location of the at least one trench, to obtain a pattern of the first catalysation layer and of the insulation layer on the substrate.

According to a second embodiment, the process of the invention further comprises the steps of:

d) Removing the photoresist layer and the first catalysation layer, except at the location of the at least one trench, to obtain a pattern of the first catalysation layer on the substrate; and

e) Providing an electroless plated layer of an insulation layer deposited onto the pattern of said first catalyzation layer, to obtain a pattern of the first catalyzation layer and of the insulation layer on the substrate.

According to another embodiment the method may further comprise the step of:

f) Providing a second catalysation layer at least on top of the pattern of the insulation layer to obtain a catalyzed insulated layer.

Preferably, this second catalysation layer is plated on the whole substrate surface, but shall adhere only to the insulation layer, not to the substrate.

According to still another embodiment, the method may further comprise the step of:

g) Providing an electroless copper plated layer on top of the catalyzed insulated layer of step f).

Accordingly, an easy way to deposit copper on the second catalytic layer, which is on top of the insulation layer, is to immerse the whole substrate in the appropriate solution, bearing in mind that copper will not adhere to the substrate because the second catalytic layer shall have a very poor adhesion on the substrate surface.

Any of the methods described here above may additionally comprise the step of cleaning the substrate prior to step a) and/or the step of micro etching the substrate prior to step a).

Uniform, thin and high quality copper layers can be obtained by Electroless Plating regardless the size of the substrate. Furthermore, a desired copper pattern can be obtained by using the “electroless-lift-off process” without copper etching.

Principles of the Lift-off process are also well known for semiconductor and LCD manufacturing, (e.g., S. Wolf and R. N. Tauber, “Silicon Processing for the VLSI Era Vol. 1”, Lattice Press). The lift-off process consists of:

1) Patterning a stencil layer on target inversely,

2) A layer to be patterned eventually is plated on all area of the target,

3) The layer on the stencil layer is removed with the stencil layer, while the other part of the layer remained on the target as a final pattern.

The lift-off is widely used for patterning of materials that cannot be easily dry-etched. In terms of LCD manufacturing, U.S. Pat. Nos. 7,005,332 and 6,998,640 disclose TFT-LCD manufacturing processes to reduce the number of masks used during such process.

U.S. Pat. No. 5,290,664 discloses a manufacturing process of gate electrode, and U.S. Pat. No. 4,599,246 discloses forming of gate, source and drain metals in contact windows. They are all using the lift-off process with corresponding dry deposition (e.g. sputtering).

Reverse pattern of photoresist is made on the substrate first. The photoresist pattern works as a stencil layer. Then, the substrate is immersed into various solutions (e.g. tin and palladium solutions) to catalyze the surface. This process is to adsorb particle-like catalysis on substrate surface. Then, an insulation layer (e.g. NIP) is plated electrolessly. The layer is plated on the catalysis. Then, the photoresist pattern is removed using a removal solution together with the insulation layer on the photoresist, while the layer on the base substrate directly is not removed. Then, the substrate is immersed into a solution (e.g. silver or palladium solution) to catalyze the surface again. This process aims at adsorbing particle-like catalysis on the substrate surface. After the second catalysation step, a copper layer is plated electrolessly. Here, Cu plating can be observed only on the insulation layer because Cu plating on glass is much less effective that on the insulation layer. As a result, the desired copper pattern can be obtained. The photoresist does not contact with the alkaline solution, and the method needs neither complicated wiring process such as a Damascene Process, nor the use of the dry/wet etching process that raises some issues as described here above. Furthermore, the photoresist layer is not in contact for more than 1 minute with operation temperatures above 90° C.

The various steps of the process of the invention are disclosed herein after according to preferred embodiments.

Cleaning of Base Substrate Step (Optional):

A solution such as a mixture of NaOH, Na₂CO₃ Na₃PO₄ is used for removing any trace of organic contaminant on the substrate (e.g. glass) by e.g. immersion of the substrate into said solution. It is possible to skip this step when the surface is clean enough or if such treatment may damage the substrate or cause unexpected chemical reactions.

This step is usually carried out for a duration which is preferably between 30 sec and 10 min at a temperature comprised between 30° C. to 100° C., more preferably between 1 min to 5 min between 50° C. to 90° C. Then the substrate is washed with de-ionized (DI) water. This cleaning step when necessary may also be carried out by using ultraviolet light or an ozone solution.

Micro Etching of the Base Substrate Step (Optional):

The aim of this step is to create micro roughness on the substrate in order to enhance the adhesion of the first layer deposited onto the substrate. It is possible to skip this step if the layer (e.g. insulation layer) has a sufficient adhesion to the substrate due to its original roughness or if such micro etching treatment may cause detrimental reactions on the glass surface. This step is done by immersing the substrate into an aqueous solution typically comprising 0.1% to 5% by volume of HF, (it may also comprise 10 g/L to 100 g/L of NH₄F) for 10 sec to 5 min, or more typically with an aqueous solution comprising 0.3% to 3% volume HF and 30 g/L to 60 g/L of NH₄F, for 30 sec to 3 min. Then the substrate is washed with DI pure water.

Photo-Resist Patterning Step (Coating, Development and Stripping)

The step is done by conventional PR patterning process comprising as the following sub-steps:
Coating of the photoresist solution onto the substrate;
Pre-baking (e.g. 90° C.) to dry such layer;
Providing a mask onto this layer;
Exposing to UV light the photo-resist through the mask;
Removing the mask;
Developing the exposed photoresist (or non-exposed, depending on the resist) used with a TMAH solution and rinsing with DI pure water
Post-baking (e.g. 150° C.) to harden the non-removed photo-resist.

First Catalysation Step:

Typically, SnCl₂ and PdCl₂ solutions can be used for this step to create an ultra thin Palladium catalysis layer onto the surface, particularly in the trenches where the photo-resist has been removed; for that purpose, the substrate is immersed into a SnCl₂ solution, then rinsed with DI pure water, then immersed into a PdCl₂ solution. Preferably, from 0.1 g/L to 50 g/L of SnCl₂ in an aqueous solution comprising 0.1% to 10% vol. HCl is used. The PdCl₂ solution is made from an aqueous solution comprising 0.01% to 5% vol. HCl and between 0.01 g/L to 5 g/L of PdCl₂. More preferably, the SnCl₂ solution comprises 1 g/L to 20 g/L of SnCl₂ dissolved into a 0.5% to 5% solution of HCl, and the PdCl₂ solution comprises 0.1 g/L to 2 g/L of PdCl₂ dissolved into a 0.05% to 1% HCl solution.

It is anticipated that the following chemical reaction may occur on the surface of the substrate: Sn²⁺+Pd²⁺ [symbol] Sn⁴⁺+Pd. Then, the substrate is immersed into a conditioning solution. This conditioning solution contains a reducing agent, which may reduce the oxidative Sn⁴⁺ on the surface and promote a reductive plating chemistry of electroless insulation layer. According to another embodiment, this conditioning solution may have a similar composition to that of the plating solution disclosed in the next step hereinafter, without Ni salt in it. According to another embodiment, a 5 g/L to 50 g/L NaH₂PO₂ solution is used for this conditioning solution. The immersion in the conditioning solution is carried out for 10 sec to 3 min.

Electroless Plating Step of the Insulation Layer

Electroless NiP or NiMP (M being selected from the group consisting of W, Mo or Re) is typically deposited as an insulation layer. NiSO₄ and NaH₂PO₂ solutions are used as Ni and P sources. NaH₂PO₂ is also used as a reducing agent. A complexing agent is selected from organic compounds having at least one carboxylic group (—COOX: X being selected from the group consisting of H, metals, alkyl) and their mixtures. Preferably, it is selected from the group consisting of acetic acid, tartaric acid, glycolic acid, lactic acid and their mixtures. For the plating of NiP, the substrate is e.g. immersed into the solution. The pH of the solution is adjusted with a pH buffer if necessary. In one embodiment, a solution of 10 g/L to 45 g/L of NiSO₄7H₂O, 3 g/L to 50 g/L of NaH₂PO₂H₂O, 5 mL/L to 50 mL/L of glycolic acid (70%) and 3 g/L of tartaric acid is used. Lead compounds can be added as a stabilizer in the range of 0.5 ppm to 10 ppm. The temperature and pH of the bath are preferably maintained in the range of 50° C. to 90° C. and 2 to 9, respectively, more preferably, 70° C. to 80° C. and 2 to 6 respectively. The plating time can be determined by the plating rate and the required thickness, typically, 30 sec to 1 min for 50 nm NiP layers. Then, the substrate is washed with DI pure water.

Photoresist (PR) Pattern Removal with an Alkaline or an Organic Solution

To remove the patterned photo-resist the substrate is immersed into a removal solution (e.g. the same alkaline solution as used in the optional cleaning step described here above) for 1 min to 15 min depending on the thickness and removal rate of the resist. Then, the substrate is washed with DI pure water. The insulation layer plated on the photo-resist surface is removed together with the photo-resist, while the layer plated on the substrate directly shall remain on the surface. The removal solution has the ability to dissolve the photoresist even when recovered with the insulation layer on the first catalysation layer.

Second Catalysation Step:

The substrate is immersed into a solution comprising AgNO₃ in NH₄OH, PdCl₂ in HCl or Pd (NH₃)₄Cl₂ in NH₄OH to deposit an ultra thin silver or palladium layer onto the substrate surface. For the silver layer, 0.1 g/L to 10 g/L of AgNO₃ in 0.01% to 1% NH₄OH solution is used typically. This step can be carried out for 10 sec to 5 min typically, preferably for 30 sec to 1 min. For the palladium layer, 0.01 g/L to 5 g/L of PdCl₂ in 0.01% to 5% HCl solution is used. More preferably, 0.1 g/L to 2 g/L of PdCl₂ is dissolved into a 0.05% to 1% HCl solution. In other embodiments, 0.1 g/L to 10 g/L of Pd (NH₃)₄Cl₂ in 0.1% to 5% NH₄OH is used.

Electroless Plating of the Copper Layer Step:

An optional reducing step can be done if this thickness uniformity and/or the resistivity of the plated Cu are not in the range of the specification required. In this case, the substrate is immersed into a conditioning solution prior to immersion into a plating solution. A solution comprising 0.1% to 5% of HCHO, more preferably 0.5% to 3% of HCHO is used. Instead of using HCHO, a solution comprising 0.1 g/L to 5 g/L of DMAB (DiMethylAmineBorane) may also be used, (more preferably 0.5 g/L to 3 g/L of DMAB).

An electroless Cu plating solution usually comprises a Cu source, a reducing agent, a complexing agent and a pH buffer as main components. As an example, a solution comprising 2 g/L to 15 g/L of CuSO₄, and a reducing agent selected from the group consisting of aldehydes, amines, hydrazines, amine boranes, glyoxylic acid, ascorbic acid, hypophosphites and any mixture thereof can be used. According to a preferred embodiment, 0.05% to 1% of HCHO is used. A Ni compound (i.e., 0.1 g/L to 10 g/L of NiCl₂) can be added to promote the Cu plating. The complexing agent may be selected from the group consisting of EDTAs, tartrates, citrates, diamines, sugar alcohols and their mixtures. In a preferred embodiment, 20 g/L to 60 g/L of potassium sodium tartrate is used. The pH of the solution is adjusted in the range of 9 to 13 with an alkaline solution such as NaOH. Sulfur compounds can also be added as stabilizer in the range of 0.1 ppm to 2 ppm.

The substrate is immersed into the mixed solution. The plating time can be determined by the plating rate and the required thickness, typically 1 min to 60 min, more preferably 5 min to 40 min for several hundreds nm Cu layers. Here, the copper layer directly deposited on the glass substrate is removed while the copper layer deposited onto the insulation layer is not removed, because Cu plating on glass is much less effective than on the insulation layer. As a result, the desired copper pattern can be obtained.

The invention will be now better understood with the following examples and comparative examples along with FIGS. 1 to 3, which represent various embodiments of the process according to this invention.

On FIG. 1, a glass substrate 1 is successively cleaned (if necessary) and micro etched (if necessary). Then a photoresist (P.R.) layer 2 is deposited on the substrate 1. A mask 3 is then placed above the P.R. layer 2 with adequate openings through which the UV light 4 can go through to create the corresponding pattern 5 in the layer 2. Then it is developed and stripped to carry out the trench 8.

A first catalysation step is then carried out to deposit a catalysation layer 6 onto the patterned layer 2 (On this FIG. 1 and any of the other drawings appended to this specification, the various layers do not have usually a thickness and shape representing their actual thickness and shape when carrying out the process; their relative thickness also are not necessarily at their right scales; these drawings only intend to give an indication on their superimposition; catalysation layers have often a thickness which is hardly detectable compared to the thickness of the photoresist layer, the insulation layer, and/or the copper layer.)

Catalyzed bumps 7 are then created at the bottom of the trench 8. Then Electroless Plating is carried out for the deposition of an insulation layer 9, 10 on the catalysation layer 6 and on the catalyzed bumps 7. Then all the photoresist pattern (which adheres less to the substrate than the catalysation layer) is removed, leaving only the desired pattern 10 of an insulation layer on the catalysation layer (catalyzed bumps) 7 and the substrate 1. (the first catalysation layer adheres better to the substrate than to the photoresist layer)

FIG. 2 discloses another embodiment which is similar to the embodiment of FIG. 1 but further comprises a step of depositing a second catalysation layer 11 on top of the insulation layer 10 to create a catalyzed insulation layer (10, 11); However the second catalysation layer (11) is preferably deposited on the whole surface of the substrate but it will not adhere as well to the substrate as it adheres to the insulation layer (10). A further step which consists of an electroless deposition of a copper pattern 12 on top of the catalyzed insulation layer (10, 11) is carried out.

FIG. 3 discloses another embodiment similar to the embodiment of FIG. 1. However after the first catalysation step, a photoresist pattern removal step is carried out, leaving only the catalyzed bumps 7 still in place. Then an Electroless Plating step is carried out to deposit the insulation layer pattern 13 onto the first catalyzation layer 7, followed by a second catalysation step to deposit the second catalysation layer 14 (preferably deposited on the overall surface as explained before) to provide a catalyzed insulation layer (13, 14) onto which is finally deposited a copper layer 15 by Electroless Plating. The copper layer (15) is plated on the second catalysation layer (14) only where it is able to properly adhere to the previous layer, i.e. on the insulation layer pattern (13) only.

The following examples disclose some of the various possible embodiments of the invention.

### EXAMPLE 1

A glass substrate was immersed into a de-greasing solution comprising NaOH, Na₂CO₃ Na₃PO₄ for 3 min at 80° C. in order to remove organic contaminants on the glass surface.

After rinsing with de-ionized water, it was immersed into a diluted HF/NH₄HF solution for 1 min to create micro roughness on the surface of said substrate. Then, a conventional positive photoresist (PR) is coated on the substrate, patterned by exposure to UV light through a mask and developed after post-baking on the substrate.

After development of the photoresist layer, the substrate is immersed into a SnCl₂ solution comprising 10 g/L of SnCl₂ in a 1% HCl solution, and then immersed into a PdCl₂ solution comprising 0.3 g/L PdCl₂ into a 0.1% HCl solution (4 min in each solution). After rinsing the substrate with D.I. water, it was immersed into a conditioning solution containing a reducing agent for 30 sec. Then, it was immersed into an insulation layer plating solution.

Table 1 shows the bath composition and the plating conditions when NiP is selected as the insulation layer plated solution:

TABLE 1

| Compositions | Conditions |
|---|---|
| NiSO₄7H₂O: 30 g/L | pH 5 by acetate buffer |
| NaH₂PO₂H2O: 30 g/L | Temperature: 70 C. |
| Lactic acid: 15 mL/L | |
| Tartaric acid: 15 g/L | |
| Lead acetate 3H₂O: | |
| 1.5 ppm | |

After rinsing with D.I. water, the substrate is immersed into an alkaline solution (the same composition as the degrease solution in this example) to remove the patterned photoresist layer. This step is carried out for 5 min. The insulation layer plated on the photoresist layer is removed together with the photoresist layer, while the layer plated directly on the substrate remains on the substrate surface.

The substrate is then immersed for 45 sec in a solution containing 1.5 g/L AgNO₃ into a 0.3% NH₄OH solution used for the second catalysation step. After rinsing the substrate with D.I. water, it is immersed into the Cu plating solution described in Table 2, with the corresponding plating conditions:

TABLE 2

| Compositions | Conditions |
|---|---|
| CuSO₄5H₂O: 7 g/L | pH 12 by NaOH |
| C₄H₄NaO₆5H₂O: 34 g/L | Room temperature |
| Na₂CO₃: 3 g/L | |
| NiCl₂: 1 g/L | |
| HCHO (37%): 13 g/L | |
| Thiourea: 0.2 ppm | |

After the copper-plating step has been carried out, the substrate is washed with DI water, to obtain the desired copper pattern. The plated Cu/NiP pattern has an excellent adhesion to the glass substrate, as demonstrated by using the tape test. The roughness and thickness uniformity of both layers are satisfactory (less than 10 nm and within 10%, respectively). The NiP layer is comprised of 91 wt % Ni and 9 wt % P.

X-ray analysis revealed that the NiP layer was amorphous. The Cu layer plated on the NiP layer had a low resistivity (3.0 μΩcm using the four point probe method). The X-ray analysis also revealed that only slight changes of the morphology of the NiP occurred after annealing of the substrate in an oven at 400° C. for 1 hour under a nitrogen atmosphere.

### EXAMPLE 2

A copper pattern is manufactured in accordance with Example 1, except that a silicon wafer is used instead of a glass substrate. The results obtained on the wafer were consistent with those obtained on the glass substrate. In order to study the Cu diffusion capability of the NiP layer, the plated Cu/NiP layers were annealed at 400 C, and an X-ray analysis is conducted to measure the amount of Cu diffused into the silicon wafer. The analysis revealed that negligible Cu diffusion occurred and that the NiP layer had a sufficient Cu barrier capability.

### COMPARATIVE EXAMPLE 1

Wet etching of the insulation layer (NiP) was conducted in order to pattern said layer on the substrate.

The NiP layer was plated on the substrate first, and then the photoresist patterning was carried out on this layer as done in example 1. Then, the insulation layer was etched using a FeCl₃ solution to pattern the NiP layer. The etching time depends on the thickness and the etching rate, but was typically 3 min to etch a 50 nm thickness layer of NiP. After etching, the substrate was immersed into acetone for 10 min to remove the photoresist. Then, the second catalysation step and the Electroless Plating of copper layer step were carried out as in Example 1.

Even though this process allowed making a copper pattern, it had been very difficult to control the shape of the copper interconnection using the wet etching, because the wet etching caused undercut etching of the NiP layer due to its isotropic nature.

### COMPARATIVE EXAMPLE 2

A copper layer was plated on the substrate as in Example 1, but without depositing a NiP layer. The copper layer obtained showed a poor adhesion onto the substrate and it was pealed off easily.

### COMPARATIVE EXAMPLE 3

All the steps of the Example 1 were carried out except the optional cleaning step of the base substrate or with a cleaning step carried out with a cleaning solution having a temperature below 30° C. Plated layers showed poor thickness uniformity and/or lack of reproducibility, when the initial glass surface was contaminated by organic components (e.g., touched by fingers and grooved or wiped). In these last cases, carrying out the cleaning step in proper conditions as disclosed here above improved uniformity and/or reproducibility.

### COMPARATIVE EXAMPLE 4

All the steps of the Example 1 were carried out except the optional micro-etching step. When the surface of the substrate does not provide micro roughness, the plated NiP layers showed poor adhesion to substrate. Creating a micro roughness of the substrate definitively help to improve adhesion. When using a commercial glass substrate for TFT-LCD panel (e.g. Corning 7059), this step is usually necessary.

### COMPARATIVE EXAMPLE 5

All the steps of the Example 1 were carried out except the first catalysation step. No NiP layer was plated on the substrate, and therefore the copper layer did not have enough adhesion to the substrate.

### COMPARATIVE EXAMPLE 6

Various comparative examples were carried out according to Example 1, except that in the first catalysation step, the concentration of SnCl₂ was either lower than 0.1 g/L or higher than 50 g/L, or that the concentration of PdCl₂ was either lower than 0.01 g/L or higher than 5 g/L. In all these examples, no NiP layer was plated on the substrate or the plated NiP layer exhibited poor thickness uniformity, a poor adhesion and/or a lack of reproducibility. Therefore, the copper layer deposited on the NiP was not satisfactory either.

### COMPARATIVE EXAMPLE 7

All the steps of Example 1 were carried out on the substrate, except that the immersion step in a conditioning) was either not carried out or that the concentration of the NaH₂PO₂ solution used was either lower than 5 g/L, or higher than 50 g/L. In all these different cases, no NiP layer was plated on the substrate or if plated such NiP layer showed poor thickness uniformity, a poor adhesion and/or a lack of reproducibility. Therefore, the copper layer deposited on the NiP layer was not satisfactory either.

### COMPARATIVE EXAMPLE 8

Various examples were conducted according to Example 1, except that the concentrations of NiSO₄7H₂O, NaH₂PO₂H₂O, lactic acid, glycolic acid, tartaric acid and lead compounds were out of the respective ranges defined here above. Either no NiP layer was plated on the substrate or if plated the NiP layer exhibited poor thickness uniformity, a poor adhesion and/or a lack of reproducibility. Therefore, the copper layer deposited on the NiP layer was not satisfactory either.

### COMPARATIVE EXAMPLE 9

Various examples were carried out in a similar way as disclosed in Example 1, except that the temperature of the NiP plating bath was below 50° C. Usually, no NiP layer was plated on the substrate or when plated such NiP layer exhibited, either poor thickness uniformity and/or a lack of reproducibility.

On the other hand, when the temperature was higher than 90° C., the plated NiP layer exhibited a poor adhesion to the glass substrate as the plating rate was too high, which might increase the internal stress of the layer. Therefore, the copper layer deposited on the NiP layer was not satisfactory either.

Furthermore, the photoresist layer did not withstand the temperature of 90° C. for more than 1 min. If the photoresist layer is very thick (to better withstand temperature), it becomes difficult to dissolve this layer during the following step.

### COMPARATIVE EXAMPLE 10

Various examples were carried out in accordance with Example 1, except that this pH of the NiP plating bath was adjusted either below 2 or above 9. In all these various examples, no NiP layer was plated onto the substrate or when plated the NiP layer did not exhibit balanced characteristics (e.g., thickness uniformity, adhesion to substrate and reproducibility). Therefore, the copper layer deposited on the NiP layer was not satisfactory either. Furthermore, when the pH of the solution is above 10, the photoresist pattern is usually destroyed (dissolved into the solution) during the NiP plating step. This makes impossible to carry out the desired Cu pattern.

### COMPARATIVE EXAMPLE 11

The various steps of Example 1 were carried out except the second catalysation step), in which case, it was usually not possible to plate a Cu layer on the NiP layer.

### COMPARATIVE EXAMPLE 12

Various examples similar to Example 1 were carried out, except that the concentration of AgNO₃ in the photoresist pattern step below 0.1 g/L or above 10 g/L. Either no Cu layer was plated or the plated Cu layer exhibited poor thickness uniformity, a poor adhesion and/or a lack of reproducibility.

### COMPARATIVE EXAMPLE 13

Various examples were carried out in accordance with Example 1, that PdCl₂ in HCl solution or Pd(NH₃)₄Cl₂ in NH₄OH solution was used instead of AgNO₃ in NH₄OH solution in the second catalysation step. This step was carried out using 0.3 g/L PdCl₂ in 0.1% HCl or 0.25 g/L Pd(NH₃)₄Cl₂ in 2% NH₄OH for a 3 min immersion. The plated Cu layer exhibited thickness uniformity, adhesion, resistivity and reproducibility comparable to those obtained in Example 1.

### COMPARATIVE EXAMPLE 14

Various examples similar to Example 1 were carried out, except that the concentrations of respectively CuSO₄5H₂O, C₄H₄KNNaO₆5H₂O, Ni compounds, HCHO, and/or sulfur compounds were out of the respective ranges defined in the electroless copper plating step above. No Cu layer was plated onto the substrate or when plated, showed poor thickness uniformity, a poor adhesion, a higher resistivity and/or a lack of reproducibility.

### COMPARATIVE EXAMPLE 15

Various examples similar to Example 1 were carried out, except that the pH of the Cu plating bath was adjusted either below 9 or above 13. No Cu layer was plated onto the substrate when the pH was below 9 as the plating kinetics was too low. On the other hand, when the pH was above 13, the Cu layer exhibited poor thickness uniformity, a poor adhesion, a higher resistivity and/or a lack of reproducibility. It has been assumed that the plating rate was too high and that this might increase the internal stress of the layer. The balanced characteristics among thickness uniformity, adhesion and reproducibility were obtained under the defined ranges of the copper Electroless Plating step.

### EXAMPLE 3

A copper pattern was fabricated as disclosed in Example 1 except that the removal of the photoresist pattern was done before the Electroless Plating of the insulation layer. The photoresist PR pattern was therefore together with the catalytic layer on the photoresist, while the catalytic layer deposited on the base substrate directly was not removed. As a result, the catalysis patterning was achieved at the end of the photoresist pattern removal. Then, the insulation layer (NiP) was plated thereafter. Since the NiP layer was plated only on the catalytic layer selectively, a patterned NiP layer could be obtained on the substrate. Then, the Cu Electroless Plating step was performed after the second catalysation step, as disclosed in Example 1.

1-7. (canceled)

8. A method of depositing a copper interconnection layer on a substrate for use in a flat panel display interconnection system, comprising the steps of:
a) coating said substrate with a photoresist layer;
b) patterning said photoresist layer to obtain a patterned photoresist layer comprising at least one trench patterned into said photoresist layer; and
c) providing a first catalyzation layer onto said patterned photoresist layer, said first catalyzation layer having a better adhesion to the substrate in the at least one trench than to the photoresist layer;

9. The method of claim 8, further comprising the steps of:
d) providing an electroless plated layer of an insulation layer deposited onto said first catalyzation layer; and
e) removing the successively superimposed photoresist layer, first catalyzation layer and insulation layer except at the location of the at least one trench, to obtain a pattern of the first catalyzation layer and of the insulation layer on the substrate.

10. The method of claim 8, further comprising the steps of:
f) removing the photoresist layer and the first catalyzation layer except at the location of the at least one trench, to obtain a pattern of the first catalyzation layer on the substrate; and
g) providing an electroless plated layer of an insulation layer deposited onto the pattern of said first catalyzation layer, to obtain a pattern of the first canalization layer and of the insulation layer on the substrate.

11. The method of claim 9, further comprising the step of:
h) providing a second catalyzation layer at least on top of the pattern of the insulation layer to obtain a catalyzed insulated layer.

12. The method of claim 11, further comprising the step of:
i) providing an electroless plated copper layer on top of the catalyzed insulated layer of step h).

13. The method of claim 8, additionally comprising the step of cleaning the substrate prior to step a).

14. The method of claim 8, additionally comprising the step of micro-etching the substrate prior to step a).
